(19) United States
(12) Patent Application Publication
(10) Pub. No.: US 2025/0142914 A1
(43) Pub. Date: May 1, 2025

(54) SILICON CARBIDE EPITAXIAL SUBSTRATE AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventor: Takaya MIYASE, Osaka (JP)

(73) Assignee: SUMITOMO ELECTRIC INDUSTRIES, LTD., Osaka (JP)

(21) Appl. No.: 18/836,937

(22) PCT Filed: Feb. 2, 2023
(86) PCT No.: PCT/JP2023/003377

§ 371 Date: Aug. 8, 2024

(30) Foreign Application Priority Data
Feb. 15, 2022 (JP) 2022-021442

(51) Int. Cl. H10D 62/832; C30B 25/20

(52) U.S. Cl. CPC H10D 62/8325; C30B 25/20

(57) ABSTRACT

A silicon carbide epitaxial substrate has: a silicon carbide substrate; and a silicon carbide layer located on the silicon carbide substrate. The silicon carbide layer includes a first region, and a second region surrounded by the first region when viewed in a plan view. The second region has a third region expanded in a <11-20> direction. The first region is composed of silicon carbide having a polytype of 4H. The third region is composed of silicon carbide having a polytype of 3C. When a surface of the first region is defined as a first surface and a surface of the third region is defined as a second surface, at least a portion of the second surface protrudes with respect to the first surface in a direction from the silicon carbide substrate toward the silicon carbide layer.

### TECHNICAL FIELD

The present disclosure relates to a silicon carbide epitaxial substrate and a method of manufacturing a silicon carbide semiconductor device. The present application claims priority based on Japanese Patent Application No. 2022-021442 filed on Feb. 15, 2022. The entire contents of the Japanese Patent Application are incorporated herein by reference.

### BACKGROUND ART

Japanese Patent Laying-Open No. 2009-124050 (PTL 1) describes a method for suppressing a gate leakage current in a gate insulating film.

### CITATION LIST

### Patent Literature

PTL 1: Japanese Patent Laying-Open No. 2009-124050

### SUMMARY OF INVENTION

A silicon carbide epitaxial substrate according to the present disclosure

includes: a silicon carbide substrate; and a silicon carbide layer located on the silicon carbide substrate. The silicon carbide layer includes a first region, and a second region surrounded by the first region when viewed in a plan view. The second region has a third region expanded in a <11-20> direction. The first region is composed of silicon carbide having a polytype of 4 H. The third region is composed of silicon carbide having a polytype of 3 C. When a surface of the first region is defined as a first surface and a surface of the third region is defined as a second surface, at least a portion of the second surface protrudes with respect to the first surface in a direction from the silicon carbide substrate toward the silicon carbide layer.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view along a line II-II of FIG. 1.

FIG. 3 is an enlarged plan view of a region III in FIG. 1.

FIG. 4 is a schematic cross sectional view along a line IV-IV of FIG. 3.

FIG. 5 is an enlarged plan view of a region V in FIG. 1.

FIG. 6 is a schematic cross sectional view along a line VI-VI of FIG. 5.

FIG. 7 is an enlarged plan view of a region VII in FIG. 1.

FIG. 8 is a schematic cross sectional view along a line VIII-VIII of FIG. 7.

FIG. 9 is a partial schematic cross sectional view showing a configuration of a manufacturing apparatus for the silicon carbide epitaxial substrate.

FIG. 10 is a flowchart schematically showing a method of manufacturing the silicon carbide epitaxial substrate according to the present embodiment.

FIG. 11 is a schematic cross sectional view showing a step of preparing a silicon carbide substrate.

FIG. 12 is a schematic cross sectional view showing a step of forming a silicon carbide layer on the silicon carbide substrate.

FIG. 13 is a schematic cross sectional view showing a step of performing chemical mechanical polishing onto the silicon carbide layer.

FIG. 14 is a flowchart showing an overview of a method of manufacturing a silicon carbide semiconductor device according to the present embodiment.

FIG. 15 is a flowchart schematically showing a step of processing the silicon carbide epitaxial substrate.

FIG. 16 is a schematic cross sectional view showing a step of preparing the silicon carbide epitaxial substrate according to the present embodiment.

FIG. 17 is a schematic cross sectional view showing an ion implantation step.

FIG. 18 is a schematic cross sectional view showing an oxide film forming step.

FIG. 19 is a schematic cross sectional view showing a configuration of the silicon carbide semiconductor device according to the present embodiment.

FIG. 20 shows respective first SICA images showing a first main surface of the silicon carbide epitaxial substrate before the CMP and after the CMP.

FIG. 21 shows respective second SICA images showing the first main surface of the silicon carbide epitaxial substrate before the CMP and after the CMP.

FIG. 22 shows respective third SICA images showing the first main surface of the silicon carbide epitaxial substrate before the CMP and after the CMP.

FIG. 23 shows respective fourth SICA images showing the first main surface of the silicon carbide epitaxial substrate before the CMP and after the CMP.

### DETAILED DESCRIPTION

### [Problem to be Solved by the Present Disclosure]

An object of the present disclosure is to provide a silicon carbide epitaxial substrate and a method of manufacturing a silicon carbide semiconductor device so as to attain an improved accuracy in inspection of screening out a non-conforming product.

### [Advantageous Effect of the Present Disclosure]

According to the present disclosure, it is possible to provide a silicon carbide epitaxial substrate and a method of manufacturing a silicon carbide semiconductor device so as to attain an improved accuracy in inspection of screening out a non-conforming product.

### [Description of Embodiments]

First, an overview of an embodiment of the present disclosure will be described. Regarding crystallographic indications in the present specification, an individual orientation is represented by [], a group orientation is represented by <>, and an individual plane is represented by ( ) and a group plane is represented by {}. A crystallographically negative index is normally expressed by putting “-” (bar) above a numeral; however, in the present specification, the crystallographically negative index is expressed by putting a negative sign before the numeral.

(1) A silicon carbide epitaxial substrate 100 according to the present disclosure includes: a silicon carbide substrate 50; and a silicon carbide layer 40 located on silicon carbide substrate 50. Silicon carbide layer 40 includes a first region 10, and a second region 20 surrounded by first region 10 when viewed in a plan view. Second region 20 has a third region 53 expanded in a <11-20> direction. First region 10 is composed of silicon carbide having a polytype of 4 H. Third region 53 is composed of silicon carbide having a polytype of 3 C. When a surface of first region 10 is defined as a first surface 13 and a surface of third region 53 is defined as a second surface 23, at least a portion of second surface 23 protrudes with respect to first surface 13 in a direction from silicon carbide substrate 50 toward silicon carbide layer 40.

(2) In silicon carbide epitaxial substrate 100 according to (1), silicon carbide layer 40 may include a main surface, the main surface being located opposite to a boundary surface between silicon carbide substrate 50 and silicon carbide layer 40, the main surface being constituted of first surface 13 and second surface 23. In the main surface, an area density of second region 20 may be more than 0 and 2.0/cm² or less.

(3) In silicon carbide epitaxial substrate 100 according to (1) or (2), in the

direction from silicon carbide substrate 50 toward silicon carbide layer 40, a distance between first surface 13 and a most-protruding portion of second surface 23 may be 5 nm or more and 100 nm or less.

(4) In silicon carbide epitaxial substrate 100 according to any one of (1) to (3), when viewed in the direction from silicon carbide layer 40 toward silicon carbide substrate 50, second region 20 may have a bottom side extending in a direction perpendicular to the <11-20> direction.

(5) In silicon carbide epitaxial substrate 100 according to any one of (1) to (4), a whole of second surface 23 may protrude with respect to first surface 13 in the direction from silicon carbide substrate 50 toward silicon carbide layer 40.

(6) In silicon carbide epitaxial substrate 100 according to any one of (1) to (4), second region 20 may have a fourth region 54 recessed with respect to first surface 13. Fourth region 54 may have a third surface 52. First surface 13 may be located between second surface 23 and third surface 52 in the direction from silicon carbide substrate 50 toward silicon carbide layer 40, and in the <11-20> direction, a width of second surface 23 may be 10 μm or more.

(7) Silicon carbide epitaxial substrate 100 according to any one of (1) to (4) may further include a downfall contiguous to second region 20.

(8) A silicon carbide epitaxial substrate 100 according to the present disclosure includes: a silicon carbide substrate 50; and a silicon carbide layer 40 located on silicon carbide substrate 50. Silicon carbide layer 40 includes a first region 10, and a second region 20 surrounded by first region 10 when viewed in a plan view. Second region 20 has a third region 53 expanded in a <11-20> direction. When first region 10 and third region 53 are observed using a confocal differential interference microscope in a state in which a light source is disposed opposite to the third region in the <11-20> direction when viewed in a plan view and is disposed in a <1-100> direction, a side of third region 53 located close to the light source is brighter than each of a surface of third region 53 and a surface of first region 10, and a side of third region 53 located away from the light source is darker than each of the surface of third region 53 and the surface of first region 10.

(9) In silicon carbide epitaxial substrate 100 according to (8), first region 10 may be composed of silicon carbide having a polytype of 4 H. Third region 53 may be composed of silicon carbide having a polytype of 3 C.

(10) A method of manufacturing a silicon carbide semiconductor device 400 according to the present disclosure includes the following steps. Silicon carbide epitaxial substrate 100 according to any one of (1) to (9) is prepared. Silicon carbide epitaxial substrate 100 is processed. [Details of Embodiments of Present Disclosure]

Hereinafter, embodiments of the present disclosure will be described in detail. In the description below, the same or corresponding elements are denoted by the same reference characters and will not be described repeatedly.

### (Silicon Carbide Epitaxial Substrate)

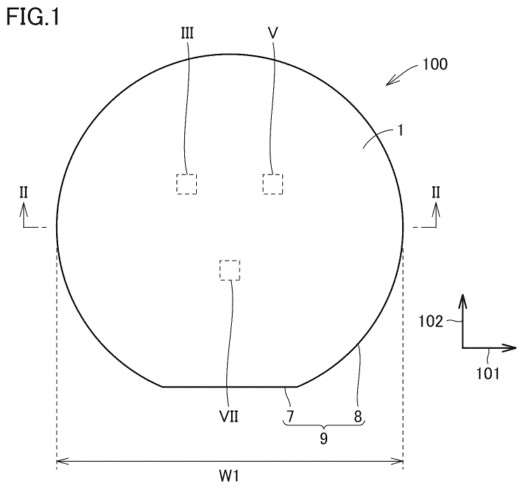

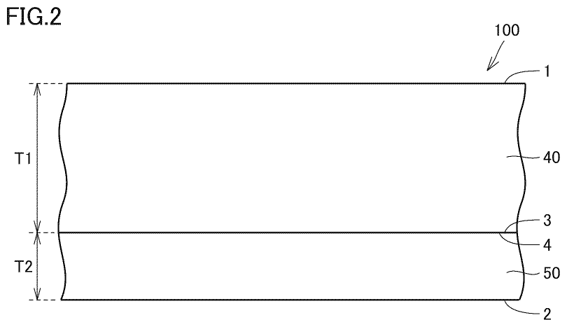

FIG. 1 is a schematic plan view showing a configuration of a silicon carbide epitaxial substrate 100 according to the present embodiment. FIG. 2 is a schematic cross sectional view along a line II-II of FIG. 1. As shown in FIGS. 1 and 2, silicon carbide epitaxial substrate 100 according to the present embodiment has a silicon carbide substrate 50 and a silicon carbide layer 40. Silicon carbide layer 40 is located on silicon carbide substrate 50. Silicon carbide layer 40 is in contact with silicon carbide substrate 50. Silicon carbide layer 40 has a first main surface 1. First main surface 1 constitutes a front surface of silicon carbide epitaxial substrate 100. Silicon carbide substrate 50 has a second main surface 2. Second main surface 2 constitutes a backside surface of silicon carbide epitaxial substrate 100.

As shown in FIG. 1, when viewed in a direction perpendicular to first main surface 1, first main surface 1 is expanded along each of a first direction 101 and a second direction 102. When viewed in the direction perpendicular to first main surface 1, first direction 101 is a direction perpendicular to second direction 102.

First direction 101 is, for example, a <11-20> direction. First direction 101 may be, for example, the [11-20] direction. First direction 101 may be a direction obtained by projecting the <11-20> direction onto first main surface 1. From another viewpoint, it can be said that first direction 101 may be a direction including a <11-20> direction component, for example.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

As shown in FIG. 1, silicon carbide epitaxial substrate 100 has an outer peripheral edge 9. Outer peripheral edge 9 has, for example, an orientation flat 7 and an arc-shaped portion 8. Orientation flat 7 extends along first direction 101. As shown in FIG. 1, orientation flat 7 is in the form of a straight line when viewed in the direction perpendicular to first main surface 1. Arc-shaped portion 8 is contiguous to orientation flat 7. Arc-shaped portion 8 has an arc shape when viewed in the direction perpendicular to first main surface 1.

First main surface 1 may be a plane inclined with respect to a {0001} plane. When first main surface 1 is inclined with respect to the {0001} plane, an inclination angle (off angle) thereof with respect to the {0001} plane is, for example, 2° or more and 6° or less. When first main surface 1 is inclined with respect to the {0001} plane, an inclination direction (off direction) of first main surface 1 is, for example, the <11-20> direction. From another viewpoint, it can be said that first direction 101 may be the off direction of first main surface 1.

As shown in FIG. 1, maximum diameter W1 (diameter) of first main surface 1 is not particularly limited, but is, for example, 100 mm (4 inches). Maximum diameter W1 may be 125 mm (5 inches) or more, or 150 mm (6 inches) or more. Maximum diameter W1 is not particularly limited. Maximum diameter W1 may be, for example, 200 mm (8 inches) or less. Maximum diameter W1 is the maximum distance between any two points on outer peripheral edge 9.

It should be noted that in the present specification, 2 inches mean 50 mm or 50.8 mm (2 inches×25.4 mm/inch). 4 inches mean 100 mm or 101.6 mm (4 inches×25.4 mm/inch). 5 inches mean 125 mm or 127.0 mm (5 inches×25.4 mm/inch). 6 inches mean 150 mm or 152.4 mm (6 inches×25.4 mm/inch). 8 inches mean 200 mm or 203.2 mm (8 inches×25.4 mm/inch).

As shown in FIG. 2, silicon carbide layer 40 has a fourth main surface 4. Fourth main surface 4 is located opposite to first main surface 1. Fourth main surface 4 is in contact with silicon carbide substrate 50. The thickness (first thickness T1) of silicon carbide layer 40 is, for example, 1 μm or more and 100 μm or less. Silicon carbide substrate 50 has a third main surface 3. Third main surface 3 is located opposite to second main surface 2. Third main surface 3 is in contact with silicon carbide layer 40. The thickness (second thickness T2) of silicon carbide substrate 50 is, for example, 200 μm or more and 500 μm or less.

Silicon carbide substrate 50 includes an n type impurity such as nitrogen (N), for example. The conductivity type of silicon carbide substrate 50 is, for example, n type. Silicon carbide layer 40 includes, for example, an n type impurity such as nitrogen. The conductivity type of silicon carbide layer 40 is, for example, n type. The concentration of the n type impurity included in silicon carbide layer 40 may be lower than the concentration of the n type impurity included in silicon carbide substrate 50.

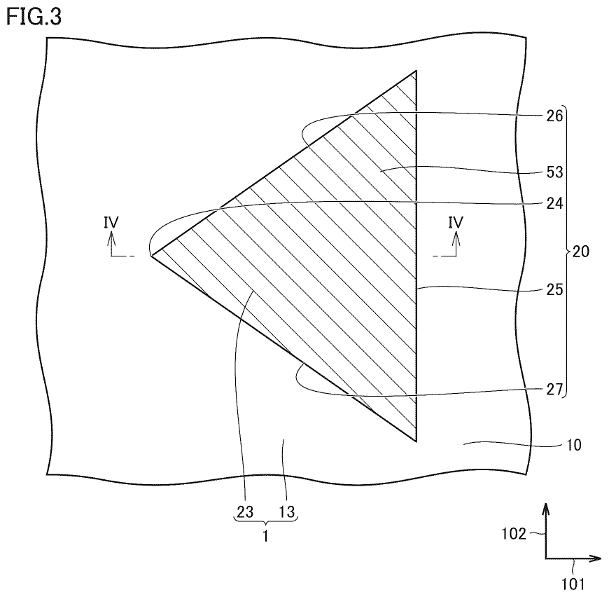

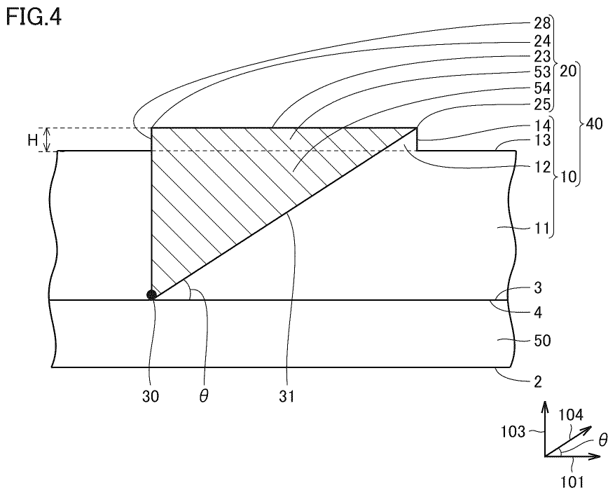

FIG. 3 is an enlarged plan view of a region III in FIG. 1. FIG. 4 is a schematic cross sectional view along a line IV-IV of FIG. 3. The cross section shown in FIG. 4 is a cross section perpendicular to second main surface 2. As shown in FIGS. 3 and 4, silicon carbide layer 40 has a first region 10 and a second region 20. When viewed in a plan view, second region 20 is surrounded by first region 10. First region 10 is composed of silicon carbide having a polytype of 4 H. Second region 20 may be composed of silicon carbide having a polytype of 3 C.

As shown in FIG. 3, when viewed in the direction from silicon carbide layer 40 toward silicon carbide substrate 50 (hereinafter also referred to as “when viewed in a plan view”), second region 20 has a third region 53 expanded in first direction 101. Specifically, second region 20 has a first side portion 26, a second side portion 27, an apex 24, and a bottom side 25. A distance between first side portion 26 and second side portion 27 in second direction 102 is increased in first direction 101. First direction 101 is the same as a direction from apex 24 toward bottom side 25. When viewed in a plan view, second region 20 is substantially triangular.

As shown in FIG. 3, when viewed in a plan view, bottom side 25 of second region 20 extends in second direction 102. When viewed in a plan view, second direction 102 is a direction perpendicular to the <11-20> direction. When viewed in a plan view, first side portion 26 is inclined to the second direction 102 side with respect to first direction 101. When viewed in a plan view, second side portion 27 is inclined to a side opposite to second direction 102 with respect to first direction 101. When viewed in a plan view, second region 20 is surrounded by first region 10.

As shown in FIG. 4, silicon carbide epitaxial substrate 100 according to the present embodiment may include a foreign matter 30. Foreign matter 30 is, for example, a carbon particle. Foreign matter 30 may be, for example, a silicon carbide particle or downfall. Second region 20 grows from foreign matter 30 as a starting point. From another viewpoint, it can be said that second region 20 is contiguous to foreign matter 30. Foreign matter 30 is located, for example, on third main surface 3 of silicon carbide substrate 50.

Second region 20 may be constituted of third region 53 and a fourth region 54. Third region 53 is contiguous to fourth region 54. Third region 53 is located on fourth region 54. First region 10 has a fifth region 11 and a sixth region 12. Sixth region 12 is located on fifth region 11. Third region 53 is composed of silicon carbide having a polytype of 3 C. Fourth region 54 may be composed of silicon carbide having a polytype of 3 C.

As shown in FIG. 4, first region 10 has a first surface 13 and fourth main surface 4. First surface 13 is located opposite to fourth main surface 4. First surface 13 may be parallel to fourth main surface 4. First surface 13 may extend along each of first direction 101 and second direction 102. First surface 13 is constituted of fifth region 11.

First region 10 has a first side surface 14. First side surface 14 is contiguous to first surface 13. First side surface 14 may be perpendicular to first surface 13. First side surface 14 extends along a third direction 103. First side surface 14 is constituted of sixth region 12.

Second region 20 has a second surface 23. Second surface 23 is constituted of third region 53. Second surface 23 extends along first direction 101. Second surface 23 may extend along second direction 102. Second surface 23 may be contiguous to first side surface 14.

Second region 20 has a second side surface 28. Second side surface 28 is contiguous to second surface 23. Second side surface 28 may be contiguous to first surface 13. Second side surface 28 may be perpendicular to second surface 23. Second side surface 28 extends along third direction 103. Second side surface 28 is constituted of third region 53. Second side surface 28 is located opposite to first side surface 14.

Second region 20 may have a bottom surface 31. Bottom surface 31 is contiguous to first region 10. Bottom surface 31 is located opposite to second surface 23. Bottom surface 31 is located at a basal plane. Bottom surface 31 extends along a fourth direction 104. Fourth direction 104 is inclined with respect to each of first direction 101 and third direction 103. A plane perpendicular to fourth direction 104 is the basal plane. Bottom surface 31 extends from fourth main surface 4 to second surface 23.

At least a portion of second surface 23 protrudes with respect to first surface 13 in the direction from silicon carbide substrate 50 toward silicon carbide layer 40. In third direction 103, at least a portion of second surface 23 is located on an outer side with respect to first surface 13. From another viewpoint, it can be said that in third direction 103, first surface 13 is located between at least a portion of second surface 23 and fourth main surface 4. As shown in FIG. 4, a whole of second surface 23 may protrude with respect to first surface 13 in the direction from silicon carbide substrate 50 toward silicon carbide layer 40.

As shown in FIG. 4, in the direction from silicon carbide substrate 50 toward silicon carbide layer 40, a distance H between first surface 13 and the most-protruding portion of second surface 23 may be, for example, 5 nm or more and 100 nm or less. The distance between first surface 13 and the most-protruding portion of second surface 23 is not particularly limited, but may be, for example, 10 nm or more or 30 nm or more. The distance between first surface 13 and the most-protruding portion of second surface 23 is not particularly limited, but may be, for example, 90 nm or less or 50 nm or less.

Distance H between first surface 13 and the most-protruding portion of second

surface 23 can be measured using a white light interferometric microscope (product name: “BW-D507”) provided by Nikon, for example. A mercury lamp is used as a light source. A measurement visual field is 256 μm×256 μm. Light emitted from the light source is split into two beams of light by a beam splitter. One of the beams of light is emitted to a reference surface. The other of the beams of light is emitted to first surface 13 and second surface 23. Light reflected from the both forms an image in a camera. Distance H between first surface 13 and the most-protruding portion of second surface 23 is measured based on information of interference fringe as obtained from an optical path difference caused by irregularities formed in first surface 13 and second surface 23.

In the present specification, the direction from silicon carbide substrate 50 toward silicon carbide layer 40 is defined as the upper side. On the other hand, a direction from silicon carbide layer 40 toward silicon carbide substrate 50 is defined as the lower side. Second surface 23 is located on the upper side with respect to first surface 13. A boundary between third region 53 and fourth region 54 may be a plane along first surface 13. Third region 53 may be a region located on the upper side with respect to first surface 13. Similarly, a boundary between fifth region 11 and sixth region 12 may be a plane along first surface 13. Sixth region 12 may be a region located on the upper side with respect to first surface 13.

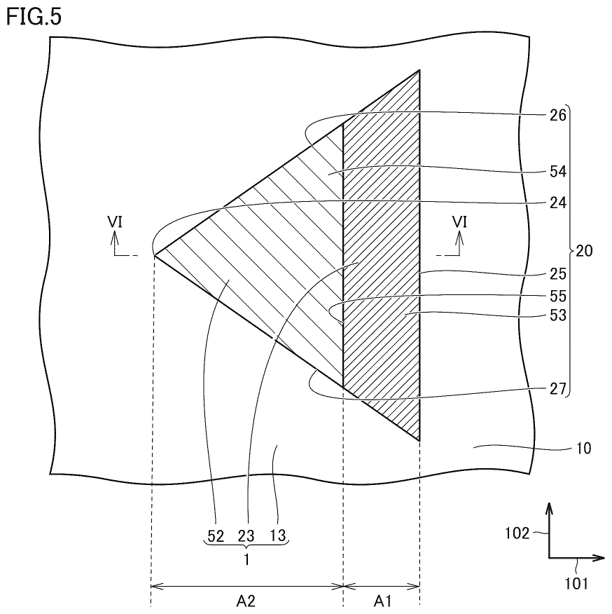

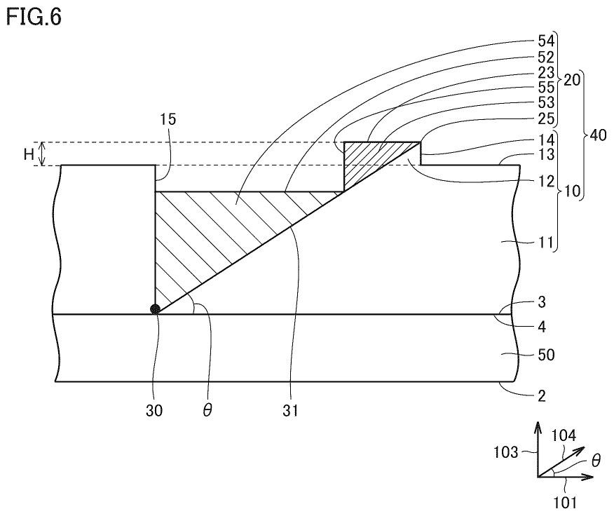

FIG. 5 is an enlarged plan view of a region V in FIG. 1. FIG. 6 is a schematic cross sectional view along a line VI-VI of FIG. 5. The cross section shown in FIG. 6 is a cross section perpendicular to second main surface 2. As shown in FIG. 5, fourth region 54 may have a third surface 52. Third surface 52 is a portion different from second surface 23. When viewed in a plan view, second surface 23 has a substantially trapezoidal shape, and third surface 52 has a substantially triangular shape. Each of second surface 23 and third surface 52 may be expanded in first direction 101. Second surface 23 is contiguous to bottom side 25. Third surface 52 is contiguous to apex 24.

As shown in FIG. 5, in first direction 101, the width (first width A1) of second surface 23 is, for example, 10 μm or more. First width A1 is not particularly limited, but may be, for example, 50 μm or more, or 100 μm or more. First width A1 is not particularly limited, but may be, for example, 1400 μm or less or 1000 μm or less. In first direction 101, the width (second width A2) of third surface 52 may be larger than first width A1.

As shown in FIG. 6, fourth region 54 is recessed with respect to first surface 13. Second region 20 may have a third side surface 55. Third side surface 55 is located between second surface 23 and third surface 52. Third side surface 55 is contiguous to each of second surface 23 and third surface 52. Third surface 52 is separated from second surface 23. Second surface 23 is constituted of third region 53. Third surface 52 is constituted of fourth region 54. Third side surface 55 is constituted of third region 53. Bottom side 25 is constituted of third region 53. Third region 53 may intersect a plane along first surface 13.

As shown in FIG. 6, each of second surface 23 and third surface 52 extends along first direction 101. Each of second surface 23 and third surface 52 may be parallel to first surface 13. Third side surface 55 extends along third direction 103. Third side surface 55 may be perpendicular to each of second surface 23 and third surface 52. First region 10 may have a fourth side surface 15. Fourth side surface 15 faces third side surface 55. Fourth side surface 15 is contiguous to first surface 13. Fourth side surface 15 extends along third direction 103. Fourth side surface 15 may be perpendicular to first surface 13.

As shown in FIG. 6, in the direction from silicon carbide substrate 50 toward silicon carbide layer 40, first surface 13 may be located between second surface 23 and third surface 52. From another viewpoint, it can be said that second surface 23 is located on the upper side with respect to first surface 13. Third surface 52 is located on the lower side with respect to first surface 13. In third direction 103, third surface 52 is located between first surface 13 and fourth main surface 4. In third direction 103, first surface 13 is located between second surface 23 and fourth main surface 4.

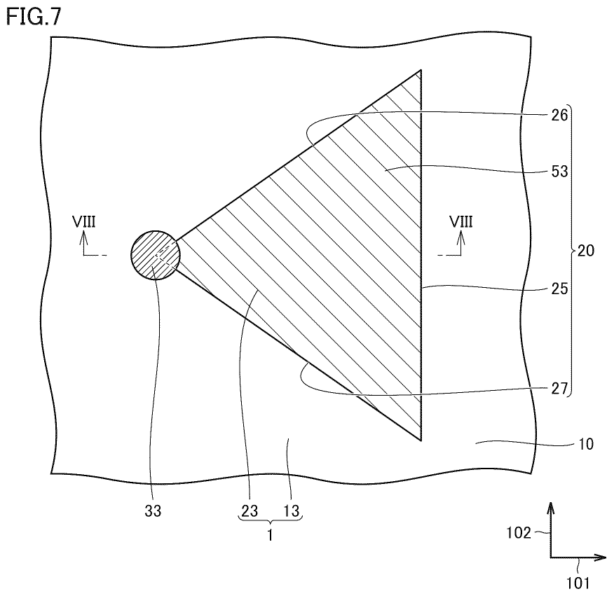

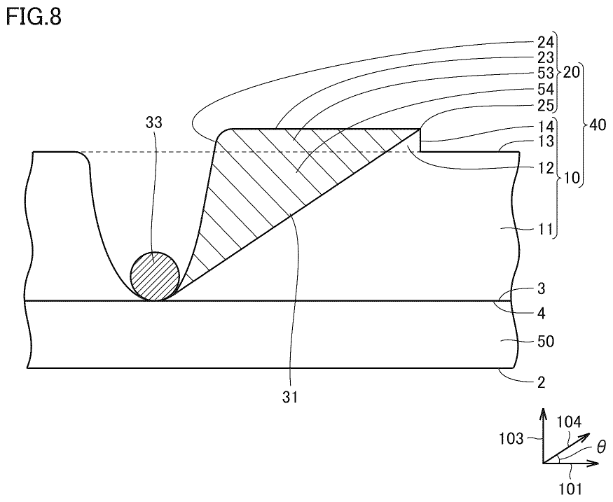

FIG. 7 is an enlarged plan view of a region VII in FIG. 1. FIG. 8 is a schematic cross sectional view along a line VIII-VIII of FIG. 7. The cross section shown in FIG. 8 is a cross section perpendicular to second main surface 2. As shown in FIG. 7, silicon carbide epitaxial substrate 100 may have a downfall 33.

Downfall 33 is, for example, a substance or the like having fallen onto silicon carbide substrate 50 from an inner wall of a film forming apparatus on which the substance or the like has been adhered. Downfall 33 is, for example, a polycrystalline silicon carbide particle. Downfall 33 may be a carbon particle or tantalum carbide particle, for example.

As shown in FIG. 7, downfall 33 is contiguous to second region 20. When viewed in a plan view, downfall 33 may be provided to overlap with each of first side portion 26 and second side portion 27. When viewed in a plan view, downfall 33 is located opposite to bottom side 25 in first direction 101.

As shown in FIG. 8, downfall 33 may be located on silicon carbide substrate 50. In third direction 103, downfall 33 may be located between first surface 13 and third main surface 3. Similarly, in third direction 103, downfall 33 may be located between second surface 23 and third main surface 3.

As shown in FIGS. 3, 5, and 7, first main surface 1 of silicon carbide layer 40 is constituted of first surface 13 and second surface 23. In first main surface 1, the area density of second region 20 is, for example, more than 0 and 2.0/cm² or less. The area density of second region 20 is not particularly limited, but may be, for example, 0.01/cm² or more, or 0.1/cm² or more. The area density of second region 20 is not particularly limited, but may be, for example, 1.0/cm² or less or 0.5/cm² or less.

Next, a method of measuring the area density of second region 20 will be described.

The area density of second region 20 is specified by observing first main surface 1 of silicon carbide epitaxial substrate 100 using a defect inspection apparatus having a confocal differential interference microscope. As the defect inspection apparatus having a confocal differential interference microscope, for example, WASAVI series “SICA 6X” provided by Lasertec can be used. The magnification of its objective lens is, for example, 10 times. Light having a wavelength of 546 nm is emitted from a light source such as a mercury xenon lamp to first main surface 1 of silicon carbide epitaxial substrate 100, and the light having been reflected is observed by a light receiving element such as a CCD (Charge-Coupled Device), for example. Second region 20 is defined in consideration of the planar shape of second region 20. Second region 20 is specified based on the observed image. “Thresh S”, which is an index of measurement sensitivity of the SICA, is set to 40, for example.

A confocal differential interference microscope image of a whole of first main surface 1 is captured while moving silicon carbide epitaxial substrate 100 in a direction parallel to first main surface 1. In the acquired confocal differential interference microscope image (hereinafter also referred to as “SICA image”), the area density of second region 20 is found. Specifically, a value obtained by dividing the number of second regions 20 by the observation area of first main surface 1 is defined as the area density of second region 20.

Next, a method of measuring the polytype of each of first region 10 and second region 20 will be described.

The polytype of each of first region 10 and second region 20 can be specified using, for example, a photoluminescence imaging apparatus (model number: PLI-200-SMH5) provided by PHOTON Design Corporation. Specifically, when excitation light is emitted to a measurement target region in first main surface 1 of silicon carbide epitaxial substrate 100, photoluminescence light is generated from the measurement target region. The photoluminescence light generated from the measurement target region is detected by a color image sensor.

The color image sensor is, for example, a CCD image sensor. The CCD element is of, for example, a back-illuminated deep depletion type. The CCD image sensor is, for example, excelon (trademark) provided by Cypress Semiconductor Corporation. An imaging wavelength range is, for example, 310 nm or more and 1024 nm or less. An element format is, for example, 1024 ch×1024 ch. An image area is, for example, 13.3 mm×13.3 mm. An element size is, for example, 13 μm×13 μm. The number of pixels is, for example, 480 pixels×640 pixels. An image size is, for example, 1.9 mm×2.6 mm.

The energy of excitation light is higher than the energy of a band gap of a hexagonal silicon carbide. As an excitation light source, for example, a mercury xenon lamp is used. The wavelength of the excitation light is, for example, 313 nm. The intensity of the excitation light is, for example, 0.1 mW/cm² or more and 2 W/cm² or less. An exposure time of the emitted light is, for example, 0.5 seconds or more and 120 seconds or less. The area of the measurement visual field is, for example, 2.6 mm×2.6 mm.

The color of first region 10 can be expressed by an RGB color space. Specifically, when the photoluminescence light generated from first region 10 by emitting the excitation light to first region 10 is expressed in the RGB color space, R may be 130 or more and 190 or less, G may be 130 or more and 190 or less, and B may be 120 or more and 180 or less. In this case, it is determined that first region 10 is composed of silicon carbide having a polytype of 4 H.

The color of second region 20 can be expressed by the RGB color space. Specifically, when the photoluminescence light generated from second region 20 by emitting the excitation light to second region 20 is expressed in the RGB color space, R may be 56 or more and 115 or less, G may be 71 or more and 128 or less, and B may be 56 or more and 123 or less. In this case, it is determined that second region 20 is composed of silicon carbide having a polytype of 3 C.

It should be noted that the RGB color space is one of color expression methods for expressing colors by red, green, and blue. In the RGB color space, the range of R is 0 or more and 255 or less, the range of G is 0 or more and 255 or less, and the range of B is 0 or more and 255 or less. Each of R, G, and B is represented by 256 gradations.

### (Manufacturing Apparatus for Silicon Carbide Epitaxial Substrate)

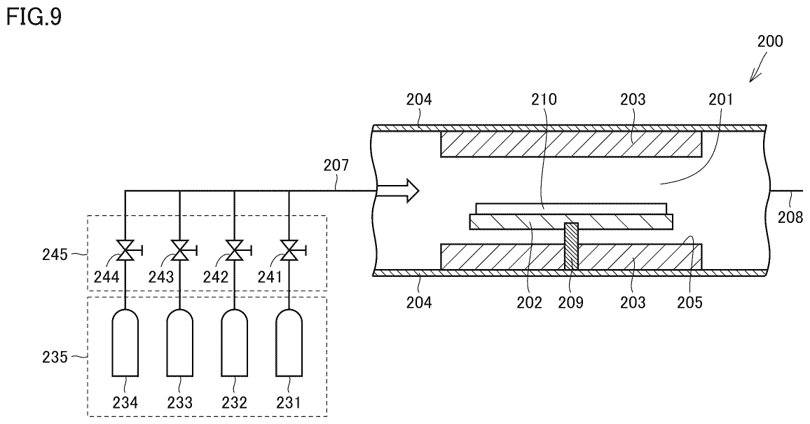

Next, a configuration of a manufacturing apparatus for silicon carbide epitaxial substrate 100 will be described. FIG. 9 is a partial schematic cross sectional view showing the configuration of the manufacturing apparatus for silicon carbide epitaxial substrate 100. A manufacturing apparatus 200 for silicon carbide epitaxial substrate 100 is, for example, a hot wall type lateral CVD (Chemical Vapor Deposition) apparatus. As shown in FIG. 9, manufacturing apparatus 200 for silicon carbide epitaxial substrate 100 mainly includes a reaction chamber 201, a gas supply unit 235, a control unit 245, a heating element 203, a quartz tube 204, a heat insulating material (not shown), and an induction heating coil (not shown).

Heating element 203 has, for example, a cylindrical shape, and forms reaction chamber 201 therein. Heating element 203 is composed of graphite, for example. Heating element 203 is provided inside quartz tube 204. The heat insulating material surrounds the outer periphery of heating element 203. The induction heating coil is wound, for example, along the outer peripheral surface of quartz tube 204. The induction heating coil can be supplied with an alternating current by an external power supply (not shown). Thus, heating element 203 is inductively heated. As a result, reaction chamber 201 is heated by heating element 203.

Reaction chamber 201 is a formed space surrounded by an inner wall surface 205 of heating element 203. A susceptor 210 that holds the silicon carbide substrate is provided in reaction chamber 201. Susceptor 210 is composed of silicon carbide. The silicon carbide substrate is placed on susceptor 210. Susceptor 210 is disposed on a stage 202. Stage 202 is rotatably supported by a rotation shaft 209. When stage 202 is rotated, susceptor 210 is rotated.

Manufacturing apparatus 200 for silicon carbide epitaxial substrate 100 further has a gas introduction port 207 and a gas discharging port 208. Gas discharging port 208 is connected to a gas discharging pump (not shown). An arrow in FIG. 9 indicates a flow of gas. The gas is introduced from gas introduction port 207 into reaction chamber 201 and is discharged from gas discharging port 208. Pressure in reaction chamber 201 is adjusted in accordance with a balance between an amount of supply of the gas and an amount of discharging of the gas.

Gas supply unit 235 is configured to supply reaction chamber 201 with a mixed gas including a source gas, a dopant gas, and a carrier gas. Specifically, gas supply unit 235 includes, for example, a first gas supply unit 231, a second gas supply unit 232, a third gas supply unit 233, and a fourth gas supply unit 234.

First gas supply unit 231 is configured to supply a first gas including carbon atoms, for example. First gas supply unit 231 is, for example, a gas cylinder provided with the first gas. The first gas is, for example, propane (C₃H₈) gas. The first gas may be, for example, methane (CH₄) gas, ethane (C₂H₆) gas, acetylene (C₂H₂) gas, or the like.

Second gas supply unit 232 is configured to supply a second gas including, for example, a silane gas. Second gas supply unit 232 is, for example, a gas cylinder provided with the second gas. The second gas is, for example, silane (SiH₄) gas. The second gas may be a mixed gas of the silane gas and a gas other than silane.

Third gas supply unit 233 is configured to supply a third gas including, for example, nitrogen atoms. Third gas supply unit 233 is, for example, a gas cylinder provided with the third gas. The third gas is a doping gas. The third gas is, for example, ammonia gas. The ammonia gas is more likely to be thermally decomposed than nitrogen gas having a triple bond.

Fourth gas supply unit 234 is configured to supply a fourth gas (carrier gas) such as hydrogen, for example. Fourth gas supply unit 234 is, for example, a gas cylinder provided with hydrogen. The fourth gas may be argon gas.

Control unit 245 is configured to control a flow rate of the mixed gas to be supplied from gas supply unit 235 to reaction chamber 201. Specifically, control unit 245 may include a first gas flow rate control unit 241, a second gas flow rate control unit 242, a third gas flow rate control unit 243, and a fourth gas flow rate control unit 244. Each control unit may be, for example, an MFC (mass flow controller). Control unit 245 is disposed between gas supply unit 235 and gas introduction port 207.

### (Method of Manufacturing Silicon Carbide Epitaxial Substrate)

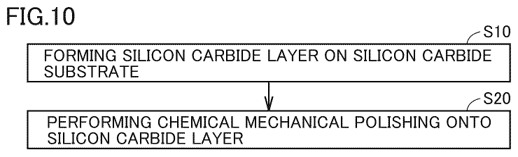

Next, a method of manufacturing silicon carbide epitaxial substrate 100 according to the present embodiment will be described. FIG. 10 is a flowchart schematically showing the method of manufacturing silicon carbide epitaxial substrate 100 according to the present embodiment. As shown in FIG. 10, the method of manufacturing silicon carbide epitaxial substrate 100 according to the present embodiment mainly includes: a step (S10) of forming the silicon carbide layer on the silicon carbide substrate; and a step (S20) of performing chemical mechanical polishing onto the silicon carbide layer.

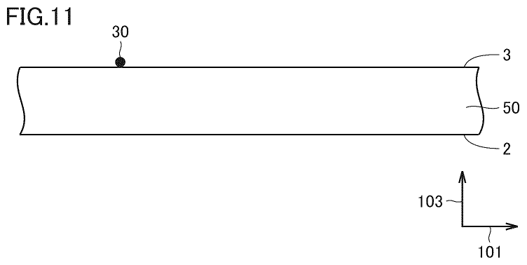

FIG. 11 is a schematic cross sectional view showing the step of preparing silicon carbide substrate 50. First, silicon carbide substrate 50 is prepared by using a wire saw to slice an ingot composed of a silicon carbide single crystal manufactured by, for example, a sublimation method. Silicon carbide substrate 50 is composed of, for example, silicon carbide having a polytype of 4 H. The diameter of silicon carbide substrate 50 is, for example, 100 mm or more. Silicon carbide substrate 50 includes an n type impurity such as nitrogen. The concentration of the n type impurity is, for example, 1×10¹⁷ cm⁻³ or more and 1×10¹⁹ cm⁻³ or less.

Silicon carbide substrate 50 has second main surface 2 and third main surface 3. Third main surface 3 is located opposite to second main surface 2. Foreign matter 30 may be present on third main surface 3. Foreign matter 30 is, for example, a carbon particle. Foreign matter 30 may be, for example, a silicon carbide particle or downfall 33.

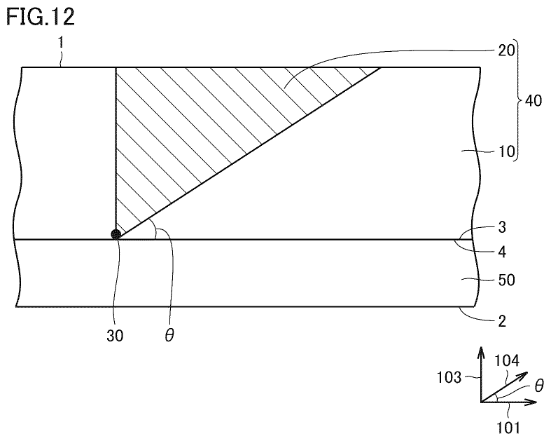

Next, the step (S10) of forming the silicon carbide layer on the silicon carbide substrate is performed. FIG. 12 is a schematic cross sectional view showing the step of forming silicon carbide layer 40 on silicon carbide substrate 50. First, silicon carbide substrate 50 is disposed on susceptor 210. Next, pressure in reaction chamber 201 is reduced. Specifically, the pressure in reaction chamber 201 is reduced from the atmospheric pressure to, for example, about 1×10⁻⁶ Pa. Next, the temperature of silicon carbide substrate 50 starts to be increased. During the temperature increase, the hydrogen (H₂) gas, which is the carrier gas, is introduced from fourth gas supply unit 234 into reaction chamber 201.

Next, the source gas, the dopant gas, and the carrier gas are supplied to reaction chamber 201. Specifically, for example, a mixed gas including silane, propane, ammonia, and hydrogen is introduced into reaction chamber 201. In reaction chamber 201, each gas is thermally decomposed. A growth temperature is, for example, 1500° C. or more and 1750° C. or less. The mixed gas may include argon instead of hydrogen.

The flow rate of the first gas (propane gas) is, for example, 29 sccm. The flow rate of the second gas (silane gas) is, for example, 46 sccm. The flow rate of the third gas (ammonia gas) is, for example, 1.5 sccm. The flow rate of the fourth gas (hydrogen gas or argon gas) is, for example, 100 slm. Reaction chamber 201 is maintained at a pressure of, for example, 2 kPa or more and 6 kPa or less. In this way, silicon carbide layer 40 is formed on silicon carbide substrate 50 by epitaxial growth.

Silicon carbide layer 40 includes first region 10 and second region 20. First region 10 is composed of silicon carbide having a polytype of 4 H. Second region 20 is composed of silicon carbide having a polytype of 3 C. Second region 20 grows from foreign matter 30 as a starting point.

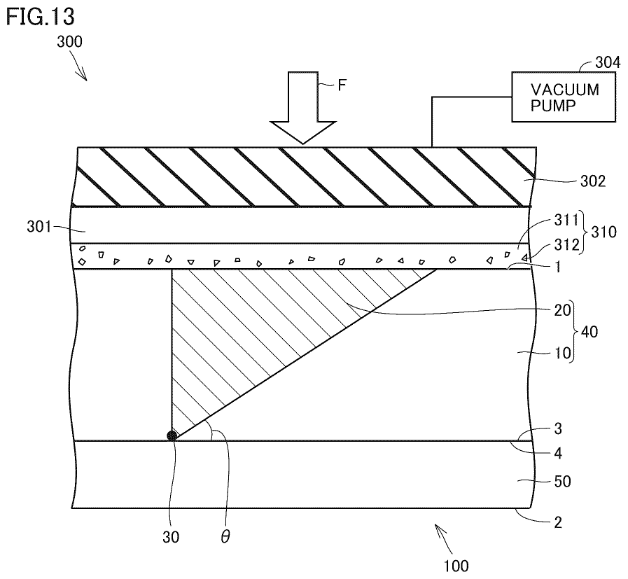

Next, the step (S20) of performing chemical mechanical polishing onto the silicon carbide layer is performed. FIG. 13 is a schematic cross sectional view showing the step of performing chemical mechanical polishing onto the silicon carbide layer. As shown in FIG. 13, by performing the CMP (Chemical Mechanical Polishing) onto silicon carbide layer 40, a portion of silicon carbide layer 40 is removed.

An amount of removal of silicon carbide layer 40 is, for example, 0.05 μm or more and 0.4 μm or less. The amount of removal of silicon carbide layer 40 is not particularly limited, but may be, for example, 0.35 μm or less, or 0.3 μm or less. The amount of removal of silicon carbide layer 40 is not particularly limited, but may be, for example, 0.10 μm or more, or 0.15 μm or more.

As shown in FIG. 13, a chemical mechanical polishing apparatus 300 has a polishing cloth 301, a polishing head 302, and a vacuum pump 304. Polishing cloth 301 is, for example, suede. A polishing liquid 310 has, for example, abrasive grains 312 and an oxidizing agent 311. Each of abrasive grains 312 is colloidal silica. Abrasive grain 312 should not be fumed silica, alumina, or the like, for example. Oxidizing agent 311 is, for example, a hydrogen peroxide solution.

As shown in FIG. 13, polishing cloth 301 is vacuum-adsorbed to polishing head 302 by using vacuum pump 304. Polishing head 302 is composed of, for example, a ceramic, stainless steel, or the like.

The chemical mechanical polishing is performed onto first main surface 1 of silicon carbide epitaxial substrate 100, thereby polishing each of first region 10 and second region 20. Under normal polishing conditions, a polishing rate for first region 10 is substantially the same as a polishing rate for second region 20. Therefore, normally, second region 20 does not protrude with respect to first region 10.

According to the method of manufacturing the silicon carbide epitaxial substrate in the present embodiment, each of first region 10 and second region 20 is polished in first main surface 1 under such a condition that the polishing rate for second region 20 is lower than the polishing rate for first region 10. From another viewpoint, it can be said that each of first region 10 and second region 20 is polished in first main surface 1 under such a condition that the thickness of second region 20 removed by the polishing becomes smaller than the thickness of first region 10 removed by the polishing. Therefore, second region 20 is formed to protrude with respect to first region 10 (see FIG. 4).

Specifically, first, first main surface 1 of silicon carbide epitaxial substrate 100 is disposed to face polishing cloth 301. Polishing liquid 310 including abrasive grains 312 is supplied between first main surface 1 and polishing cloth 301. The rotation speed of polishing head 302 is, for example, 60 rpm. The rotation speed of a surface plate provided with polishing cloth 301 is, for example, 60 rpm. A processing pressure F is, for example, 500 g/cm².

In order to increase distance H (see FIG. 4) between first surface 13 and the most-protruding portion of second surface 23, the following polishing liquid is desirably used. Abrasive grains having an average particle size of about 5 nm are used in the step of polishing the silicon carbide epitaxial substrate according to the present embodiment, although abrasive grains having an average particle size of about 20 nm or more and 30 nm or less are normally used. Further, nitric acid is used as the oxidizing agent. In this way, silicon carbide epitaxial substrate 100 according to the present embodiment is manufactured (see FIG. 1).

### (Method of Manufacturing Silicon Carbide Semiconductor Device)

Next, a method of manufacturing a silicon carbide semiconductor device 400 according to the present embodiment will be described.

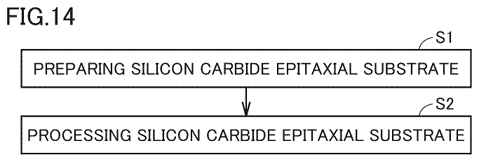

FIG. 14 is a flowchart schematically showing the method of manufacturing the silicon carbide semiconductor device according to the present embodiment. As shown in FIG. 14, the method of manufacturing the silicon carbide semiconductor device according to the present embodiment mainly includes a step (S1) of preparing the silicon carbide epitaxial substrate and a step (S2) of processing the silicon carbide epitaxial substrate.

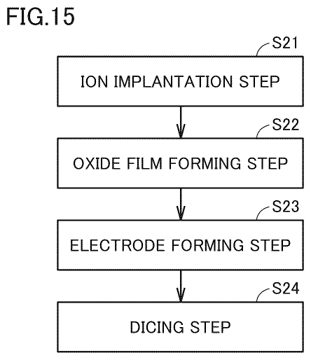

A method of manufacturing a MOSFET (Metal Oxide Semiconductor Field Effect Transistor) serving as an example of the silicon carbide semiconductor device will be described. FIG. 15 is a flowchart schematically showing the step of processing silicon carbide epitaxial substrate 100. As shown in FIG. 15, the step (S2) of processing silicon carbide epitaxial substrate 100 includes, for example, an ion implantation step (S21), an oxide film forming step (S22), an electrode forming step (S23), and a dicing step (S24).

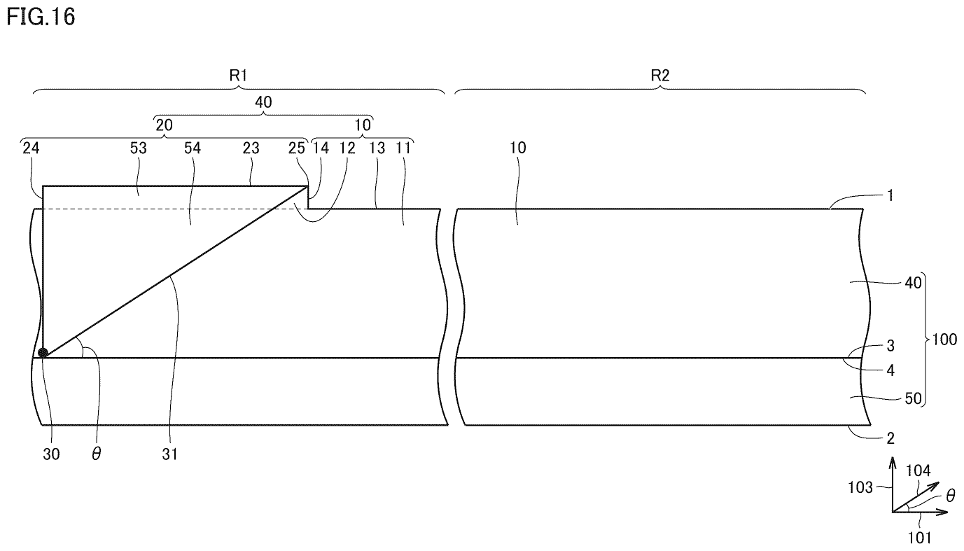

First, the step (S1) of preparing the silicon carbide epitaxial substrate is performed. Specifically, silicon carbide epitaxial substrate 100 is prepared by the above-described method of manufacturing silicon carbide epitaxial substrate 100. FIG. 16 is a schematic cross sectional view showing the step of preparing silicon carbide epitaxial substrate 100 according to the present embodiment. As shown in FIG. 16, silicon carbide epitaxial substrate 100 has a first substrate region R1 and a second substrate region R2. First substrate region R1 has first region 10 and second region 20. Second region 20 protrudes with respect to first region 10. Second substrate region R2 has first region 10. Second substrate region R2 does not have second region 20. First substrate region R1 in FIG. 16 corresponds to FIG. 4.

Next, the step (S2) of processing silicon carbide epitaxial substrate 100 is performed. Specifically, the silicon carbide semiconductor device is manufactured by processing silicon carbide epitaxial substrate 100. The term “processing” includes various types of processing such as ion implantation, heat treatment, etching, oxide film formation, electrode formation, and dicing, for example. That is, the substrate processing step may include at least any one of the ion implantation, the heat treatment, the etching, the oxide film formation, the electrode formation, and the dicing.

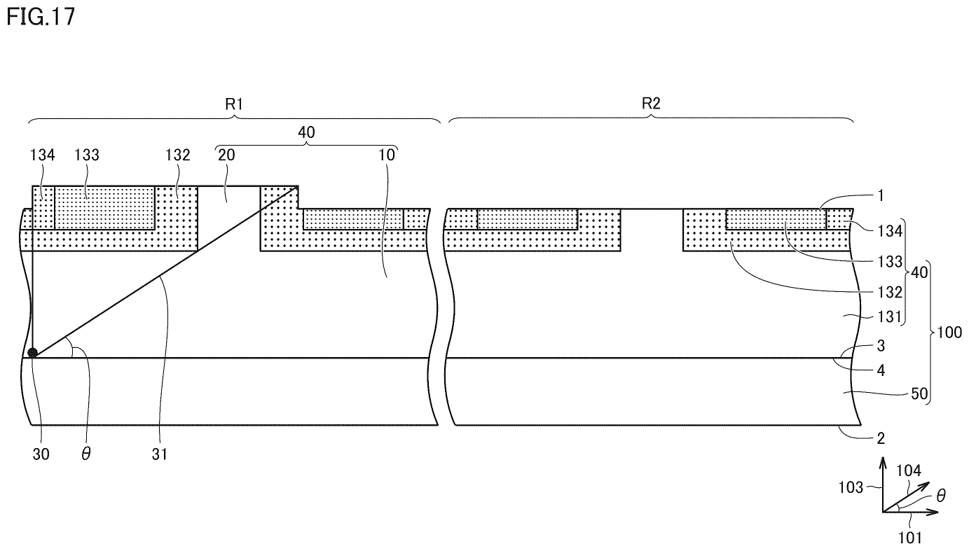

First, the ion implantation step (S21) is performed. FIG. 17 is a schematic cross sectional view showing the ion implantation step. First, for example, a p type impurity such as aluminum (A1) is implanted into first main surface 1 on which a mask (not shown) provided with an opening is formed. Thus, a body region 132 having p type conductivity is formed. The p type impurity is implanted into first region 10. The p type impurity may be implanted into second region 20. Body region 132 is formed in first region 10. Body region 132 may be formed in a portion of second region 20.

Next, an n type impurity such as phosphorus (P) is implanted into a predetermined position in body region 132, for example. Thus, a source region 133 having n type conductivity is formed. The n type impurity is implanted into first region 10. The n type impurity region may be implanted into second region 20. Source region 133 is formed in first region 10. Source region 133 may be formed in a portion of second region 20.

Next, a p type impurity such as aluminum is implanted into a predetermined position in source region 133. Thus, a contact region 134 having p type conductivity is formed. The p type impurity is implanted into first region 10. The p type impurity region may be implanted into second region 20. Contact region 134 is formed in first region 10. Contact region 134 may be formed in a portion of second region 20.

In silicon carbide layer 40, a portion other than body region 132, source region 133, and contact region 134 serves as a drift region 131. Source region 133 is separated from drift region 131 by body region 132. The ion implantation may be performed with silicon carbide epitaxial substrate 100 being heated to about 300°° C. or more and 600° C. or less. After the ion implantation, activation annealing is performed onto silicon carbide epitaxial substrate 100. By the activation annealing, the impurities implanted in silicon carbide layer 40 are activated to generate a carrier in each region. An atmosphere of the activation annealing is, for example, an argon (Ar) atmosphere. A temperature of the activation annealing is, for example, about 1800° C. A time of the activation annealing is, for example, about 30 minutes.

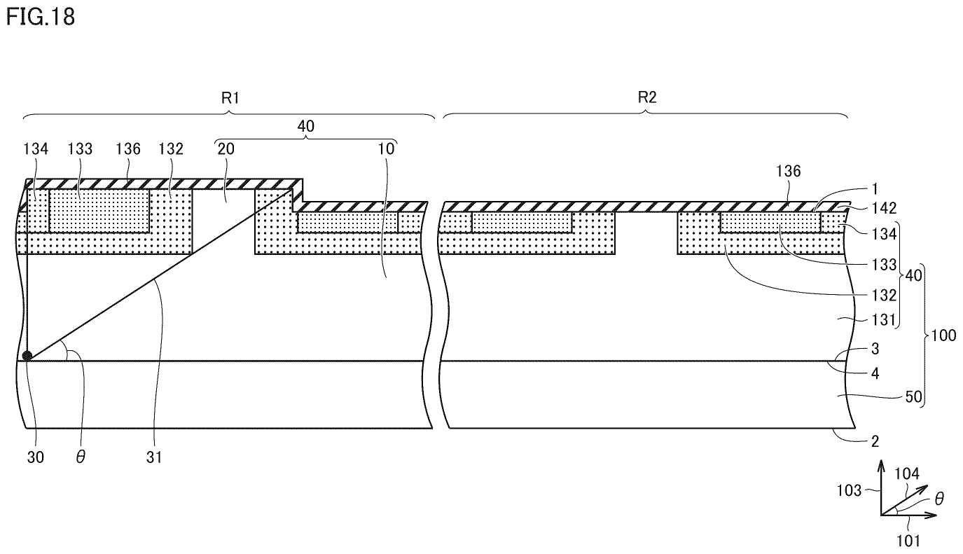

Next, the oxide film forming step (S22) is performed. FIG. 18 is a schematic cross sectional view showing the oxide film forming step. For example, by heating silicon carbide epitaxial substrate 100 in an atmosphere including oxygen, a gate oxide film 136 is formed in first main surface 1. Gate oxide film 136 is composed of, for example, silicon dioxide or the like. Gate oxide film 136 functions as a gate insulating film. A temperature of the thermal oxidation treatment is, for example, about 1300° C. A time of the thermal oxidation treatment is, for example, about 30 minutes.

Gate oxide film 136 is formed in contact with each of first region 10 and second region 20. As shown in FIG. 18, second region 20 protrudes with respect to first region 10. Therefore, a step is formed in gate oxide film 136 at the boundary between first region 10 and second region 20. A gate leakage current is likely to be generated in the portion in which the step is formed.

Next, the electrode forming step (S23) is performed. Specifically, a gate electrode 141 is formed on gate oxide film 136. Gate electrode 141 is formed by, for example, a CVD (Chemical Vapor Deposition) method. Gate electrode 141 is composed of, for example, polysilicon having electric conductivity, or the like. Gate electrode 141 is formed at a position facing source region 133 and body region 132. A portion of gate electrode 141 may be formed on the step formed in gate oxide film 136.

Next, an interlayer insulating film 137 covering gate electrode 141 is formed. Interlayer insulating film 137 is formed by, for example, a CVD method. Interlayer insulating film 137 is composed of, for example, silicon dioxide or the like. Interlayer insulating film 137 is formed in contact with gate electrode 141 and gate oxide film 136. Next, portions of gate oxide film 136 and interlayer insulating film 137 are removed by etching. Thus, source region 133 and contact region 134 are exposed from gate oxide film 136.

Next, a source electrode 142 is formed on the exposed portion by, for example, a sputtering method. Source electrode 142 is composed of, for example, titanium, aluminum, silicon, or the like. After source electrode 142 is formed, source electrode 142 and silicon carbide epitaxial substrate 100 are heated, for example, at a temperature of about 900°° C. or more and 1100° C. or less. Thus, source electrode 142 and silicon carbide epitaxial substrate 100 are brought into ohmic contact with each other. Next, a wiring layer 138 is formed in contact with source electrode 142. Wiring layer 138 is composed of, for example, a material including aluminum. Next, a drain electrode 143 is formed on second main surface 2. Drain electrode 143 is composed of, for example, an alloy including nickel and silicon (for example, NiSi or the like). In this way, silicon carbide semiconductor device 400 is manufactured.

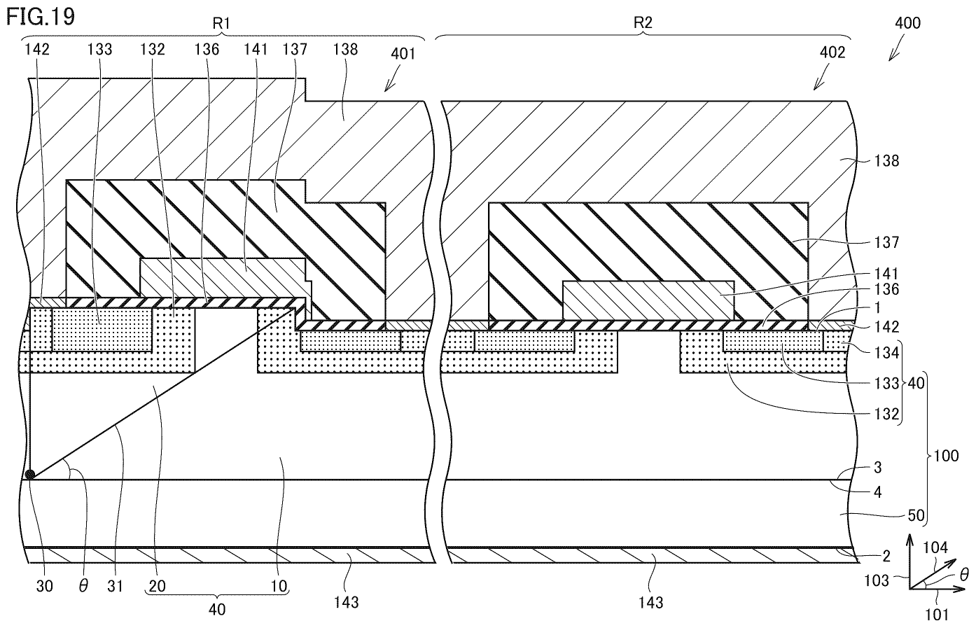

FIG. 19 is a schematic cross sectional view showing a configuration of the silicon carbide semiconductor device according to the present embodiment. As shown in FIG. 19, silicon carbide semiconductor device 400 mainly has silicon carbide epitaxial substrate 100, gate oxide film 136, interlayer insulating film 137, gate electrode 141, source electrode 142, drain electrode 143, and wiring layer 138. Silicon carbide semiconductor device 400 has a first semiconductor device portion 401 and a second semiconductor device portion 402. First semiconductor device portion 401 is formed in first substrate region R1. Second semiconductor device portion 402 is formed in second substrate region R2.

The step is formed in gate oxide film 136 of first semiconductor device portion 401. Therefore, in first semiconductor device portion 401, a gate leakage current is likely to be generated. A breakdown voltage of first semiconductor device portion 401 measured in an initial characteristic inspection is low. As a result, first semiconductor device portion 401 is highly likely to be determined as a non-conforming product in terms of breakdown voltage. On the other hand, no step is formed in gate oxide film 136 of second semiconductor device portion 402. Therefore, in second semiconductor device portion 402, a gate leakage current is less likely to be generated. A breakdown voltage of second semiconductor device portion 402 measured in the initial characteristic inspection is high. As a result, first semiconductor device portion 401 is highly likely to be determined as a conforming product.

It should be noted that the method of manufacturing silicon carbide semiconductor device 400 according to the present disclosure has been described above by illustrating the planar type MOSFET; however, the manufacturing method according to the present disclosure is not limited thereto. The manufacturing method according to the present disclosure is applicable to a silicon carbide semiconductor device 400 such as a trench type MOSFET, an IGBT (Insulated Gate Bipolar Transistor), an SBD (Schottky Barrier Diode), a thyristor, a GTO (Gate Turn Off Tyristor), a PN diode, or the like, for example.

### (SICA Images)

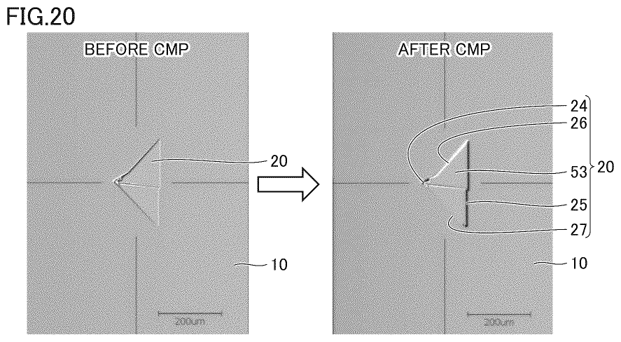

FIG. 20 shows respective first SICA images showing first main surface 1 of silicon carbide epitaxial substrate 100 before the CMP and after the CMP. The region shown in FIG. 20 corresponds to the region shown in FIG. 3.

First main surface 1 of silicon carbide layer 40 is observed in a state in which a light source of a confocal differential interference microscope is disposed on the upper left. When viewed in a plan view, the light source is disposed opposite to third region 53 in the <11-20> direction and is disposed in the <1-100> direction. When a protrusion is formed in first main surface 1, a surface of the protrusion facing the light source is bright, and a surface of the protrusion opposite to the light source is dark. From another viewpoint, it can be said that the surface of the protrusion located close to the light source is bright, and the surface of the protrusion located away from the light source is dark.

As shown in the image on the left side of FIG. 20, before the CMP, second region 20 is recessed with respect to first region 10. On the other hand, as shown in the image on the right side of FIG. 20, after the CMP, second region 20 protrudes with respect to first region 10. Second region 20 has first side portion 26, second side portion 27, bottom side 25, apex 24, and third region 53.

After the CMP, first side portion 26 is brighter than the surface of first region 10. Bottom side 25 is darker than second side portion 27. First side portion 26 is brighter than second side portion 27. Bottom side 25 may be the darkest. That is, first side portion 26 of third region 53 located close to the light source is brighter than each of the surface of third region 53 and the surface of first region 10. Bottom side 25 of third region 53 located away from the light source is darker than each of the surface of third region 53 and the surface of first region 10. The brightness of the surface of first region 10 and the brightness of the surface of third region 53 may be substantially the same. Apex 24 may be darker than each of the surface of third region 53 and the surface of first region 10.

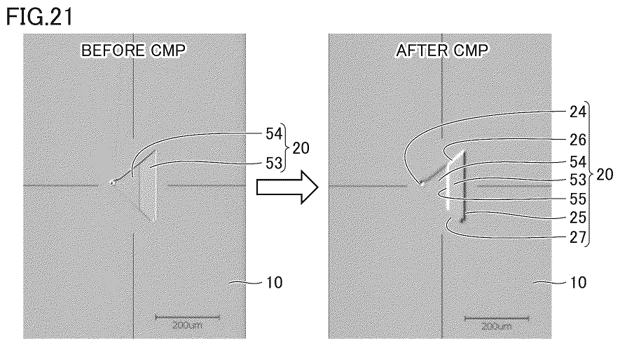

FIG. 21 shows respective second SICA images showing first main surface 1 of silicon carbide epitaxial substrate 100 before the CMP and after the CMP. The region shown in FIG. 21 corresponds to the region shown in FIG. 5.

Second region 20 may have third region 53 and fourth region 54. As shown in the image on the left side of FIG. 21, before the CMP, each of third region 53 and fourth region 54 is recessed with respect to first region 10. On the other hand, as shown in the image on the right side of FIG. 21, after the CMP, third region 53 protrudes with respect to first region 10. Fourth region 54 is recessed with respect to first region 10.

After the CMP, third side surface 55 located at the boundary between third region 53 and fourth region 54 is brighter than the surface of first region 10. First side portion 26 formed by third region 53 is brighter than the surface of first region 10. First side portion 26 formed by fourth region 54 is darker than the surface of first region 10. Bottom side 25 formed by third region 53 is darker than the surface of first region 10. The surface of third region 53 and the surface of first region 10 may have substantially the same brightness.

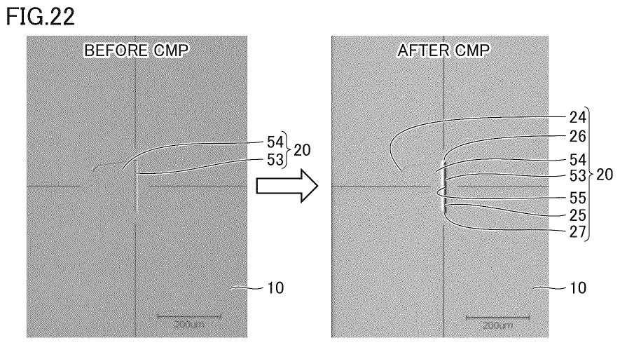

FIG. 22 shows respective third SICA images showing first main surface 1 of silicon carbide epitaxial substrate 100 before the CMP and after the CMP. The region shown in FIG. 22 corresponds to the region shown in FIG. 5.

As shown in FIG. 22, when the width of third surface 52 in the leftward/rightward direction of the SICA image is small, third region 53 seems to have a shape of bar extending in the upward/downward direction. However, when third region 53 is observed in an enlarged manner, third region 53 is expanded in the <11-20> direction. In other words, third region 53 has a trapezoidal shape when viewed in a plan view. After the CMP, third side surface 55 located at the boundary between third region 53 and fourth region 54 is brighter than the surface of first region 10. Bottom side 25 formed by third region 53 is darker than the surface of first region 10.

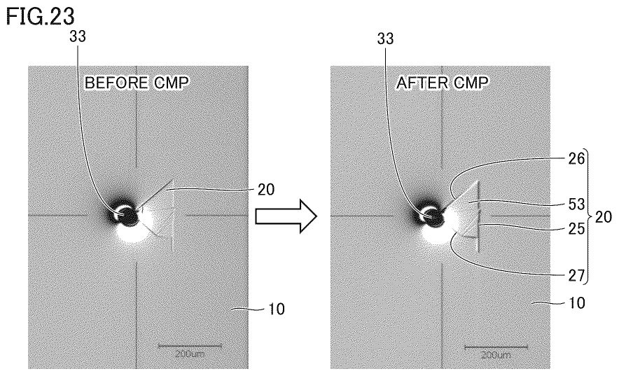

FIG. 23 shows respective fourth SICA images showing first main surface 1 of silicon carbide epitaxial substrate 100 before the CMP and after the CMP. The region shown in FIG. 23 corresponds to the region shown in FIG. 7.

As shown in FIG. 23, downfall 33 may be present in silicon carbide epitaxial substrate 100. Downfall 33 is contiguous to second region 20. When viewed in a plan view, third region 53 is located between downfall 33 and bottom side 25. As shown in the image on the right side of FIG. 21, after the CMP, the upper left surface of downfall 33 is displayed to be dark. The lower right surface of downfall 33 is displayed to be bright. First side portion 26 of third region 53 located close to the light source is brighter than each of the surface of third region 53 and the surface of first region 10. Bottom side 25 of third region 53 located away from the light source is darker than each of the surface of third region 53 and the surface of first region 10.

As described above, when first region 10 and third region 53 are observed using the confocal differential interference microscope in the state in which the light source is disposed on the upper left, the side of third region 53 located close to the light source is brighter than each of the surface of third region 53 and the surface of first region 10, and the side of third region 53 located away from the light source is darker than each of the surface of third region 53 and the surface of first region 10.

The confocal differential interference microscope is, for example, WASAVI series “SICA 6X”, which is a defect inspection apparatus provided by Lasertec. First, luminance (brightness) of an measurement target object is set in a calibration step referred to as “light calibration”. The setting value for the luminance is referred to as “Target brightness”. Before observing first main surface 1 of silicon carbide epitaxial substrate 100, the output and the like of the light source are adjusted such that a luminance for displaying the measurement target coincides with the setting value. The setting value (Target brightness) for the luminance is 2000.

Each of the SICA images to be observed is scaled down to 256 gradations. Specifically, the SICA image is expressed in a gray scale of 256 gradations. A range of the value of luminance (brightness) is 0 or more and 255 or less. When the value of luminance is 0, the SICA image is displayed to be the darkest. In other words, the color when the value of luminance is 0 is black. When the value of luminance is 255, the SICA image is displayed to be the brightest. In other words, the color when the value of luminance is 255 is white.

Next, functions and effects of silicon carbide epitaxial substrate 100 and the method of manufacturing silicon carbide semiconductor device 400 according to the present embodiment will be described.

A killer defect involving a triangular defect, a downfall, or the like normally has a region composed of silicon carbide having a polytype of 3 C. When such a killer defect is present in silicon carbide epitaxial substrate 100, coverage of the gate oxide film formed on the killer defect is deteriorated. As a result, a gate leakage current is generated in a semiconductor element formed in the region in which the killer defect is present. In many cases, the semiconductor element formed in the region in which the killer defect is present is determined as being non-conforming in terms of breakdown voltage or the like in an initial characteristic inspection at a wafer stage. The semiconductor element determined as being non-conforming in terms of breakdown voltage is classified as a non-conforming product and is not normally shipped out.

However, when the size of the killer defect is small, the coverage of the gate oxide film formed on the killer defect is not deteriorated so much. Therefore, the semiconductor element formed in the region including such a killer defect may pass the initial characteristic inspection. The semiconductor element having passed the initial characteristic inspection is subjected to various post processes such as a wafer dicing process and is then shipped out as a semiconductor device.

The semiconductor device including the killer defect may cause characteristic deterioration (reliability failure) during operation. Therefore, it is desirable that all the semiconductor elements each including a killer defect are determined as being non-conforming at the stage of the initial characteristic inspection and are removed.

Silicon carbide layer 40 of silicon carbide epitaxial substrate 100 according to the present disclosure includes first region 10 and second region 20. First region 10 is composed of silicon carbide having a polytype of 4 H. Second region 20 is composed of silicon carbide having a polytype of 3 C. When the surface of first region 10 is defined as first surface 13 and the surface of second region 20 is defined as second surface 23, at least a portion of second surface 23 protrudes with respect to first surface 13 in the direction from silicon carbide substrate 50 toward silicon carbide layer 40.

In silicon carbide epitaxial substrate 100, when the gate oxide film is formed to cover first surface 13 and second surface 23, the step is formed in the gate oxide film. That is, the coverage of the gate oxide film is deteriorated. As a result, the step portion becomes a leakage path to result in an increased gate leakage current. As described above, in the semiconductor element formed in the region including the killer defect, the gate leakage failure is proactively caused. Thus, in the initial characteristic inspection, the semiconductor element formed in the region composed of silicon carbide having a polytype of 3 C can be effectively detected.

As described above, silicon carbide semiconductor device 400 including the semiconductor element formed in the region composed of silicon carbide having a polytype of 3 C may cause characteristic deterioration (reliability failure) during operation. Since the semiconductor element formed in the region composed of silicon carbide having a polytype of 3 C is detected at the stage of the initial characteristic inspection, the semiconductor element can be accurately screened out. As a result, silicon carbide semiconductor device 400 that may otherwise cause characteristic deterioration (reliability failure) during operation can be suppressed from being shipped out.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface; 2: second main surface; 3: third main surface; 4: fourth main surface; 7: orientation flat; 8: arc-shaped portion; 9: outer peripheral edge; 10: first region; 11: fifth region; 12: sixth region; 13: first surface; 14: first side surface; 15:

fourth side surface; 20: second region; 23: second surface; 24: apex; 25: bottom side; 26: first side portion; 27: second side portion; 28: second side surface; 30: foreign matter; 31: bottom surface; 33: downfall; 40: silicon carbide layer; 50: silicon carbide substrate; 52: third surface; 53: third region; 54: fourth region; 55: third side surface; 100: silicon carbide epitaxial substrate; 101: first direction; 102: second direction; 103: third direction; 104: fourth direction; 131: drift region; 132: body region; 133: source region; 134: contact region; 136: gate oxide film; 137: interlayer insulating film; 138: wiring layer; 141: gate electrode; 142: source electrode; 143: drain electrode; 200: manufacturing apparatus; 201: reaction chamber; 202: stage; 203: heating element; 204: quartz tube; 205: inner wall surface; 207: gas introduction port; 208: gas discharging port; 209: rotation shaft; 210: susceptor; 231: first gas supply unit; 232: second gas supply unit; 233: third gas supply unit; 234: fourth gas supply unit; 235: gas supply unit; 241: first gas flow rate control unit; 242: second gas flow rate control unit; 243: third gas flow rate control unit; 244: fourth gas flow rate control unit; 245: control unit; 300: chemical mechanical polishing apparatus; 301: polishing cloth; 302: polishing head; 304: vacuum pump; 310: polishing liquid; 311: oxidizing agent; 312: abrasive grain; 400: silicon carbide semiconductor device; 401: first semiconductor device portion; 402: second semiconductor device portion; A1: first width; A2: second width; F: processing pressure; H: distance; R1: first substrate region; R2: second substrate region; T1: first thickness; T2: second thickness; W1: maximum diameter.

1. A silicon carbide epitaxial substrate comprising:
a silicon carbide substrate; and
a silicon carbide layer located on the silicon carbide substrate, wherein
the silicon carbide layer includes a first region, and a second region surrounded by the first region when viewed in a plan view,
the second region has a third region expanded in a <11-20> direction,
the first region is composed of silicon carbide having a polytype of 4 H,
the third region is composed of silicon carbide having a polytype of 3 C, and
when a surface of the first region is defined as a first surface and a surface of the third region is defined as a second surface, at least a portion of the second surface protrudes with respect to the first surface in a direction from the silicon carbide substrate toward the silicon carbide layer.

2. The silicon carbide epitaxial substrate according to claim 1, wherein
the silicon carbide layer includes a main surface, the main surface being located opposite to a boundary surface between the silicon carbide substrate and the silicon carbide layer, the main surface being constituted of the first surface and the second surface, and
in the main surface, an area density of the second region is more than 0 and 2.0/cm² or less.

3. The silicon carbide epitaxial substrate according to claim 1, wherein in the direction from the silicon carbide substrate toward the silicon carbide layer, a distance between the first surface and a most-protruding portion of the second surface is 5 nm or more and 100 nm or less.

4. The silicon carbide epitaxial substrate according to claim 1, wherein when viewed in the direction from the silicon carbide layer toward the silicon carbide substrate, the second region has a bottom side extending in a direction perpendicular to the <11-20> direction.

5. The silicon carbide epitaxial substrate according to claim 1, wherein a whole of the second surface protrudes with respect to the first surface in the direction from the silicon carbide substrate toward the silicon carbide layer.

6. The silicon carbide epitaxial substrate according to claim 1, wherein
the second region has a fourth region recessed with respect to the first surface,
the fourth region has a third surface,
the first surface is located between the second surface and the third surface in the direction from the silicon carbide substrate toward the silicon carbide layer, and
in the <11-20> direction, a width of the second surface is 10 μm or more.

7. The silicon carbide epitaxial substrate according to claim 1, further comprising a downfall contiguous to the second region.

8. A silicon carbide epitaxial substrate comprising:
a silicon carbide substrate; and
a silicon carbide layer located on the silicon carbide substrate, wherein the silicon carbide layer includes a first region, and a second region surrounded by the first region when viewed in a plan view,
the second region has a third region expanded in a <11-20> direction,
when the first region and the third region are observed using a confocal differential interference microscope in a state in which a light source is disposed opposite to the third region in the <11-20> direction when viewed in a plan view and is disposed in a <1-100> direction, a side of the third region located close to the light source is brighter than each of a surface of the third region and a surface of the first region, and a side of the third region located away from the light source is darker than each of the surface of the third region and the surface of the first region.

9. The silicon carbide epitaxial substrate according to claim 8, wherein
the first region is composed of silicon carbide having a polytype of 4 H, and
the third region is composed of silicon carbide having a polytype of 3 C.

10. A method of manufacturing a silicon carbide semiconductor device, the method comprising:
preparing the silicon carbide epitaxial substrate according to claim 1; and
processing the silicon carbide epitaxial substrate.
